(19) United States
(12) Patent Application Publication
(10) Pub. No.: US 2025/0282608 A1
(43) Pub. Date: Sep. 11, 2025

(54) SEALED CAVITY FOR A CAPACITIVE SENSING DEVICE

(71) Applicant: INVENSENSE, INC., San Jose, CA (US)

(72) Inventors: Chung-Hsien Lin, Hsinchu City (TW); Joseph Seeger, MENLO PARK, CA (US)

(21) Appl. No.: 18/953,016

(22) Filed: Nov. 19, 2024

Related U.S. Application Data
(60) Provisional application No. 63/562,509, filed on Mar. 7, 2024.

(51) Int. Cl. B81B 3/00; B81C 1/00

(52) U.S. Cl. CPC B81B 3/0072; B81C 1/00182; B81B 2201/0257; B81B 2203/0127; B81B 2203/0315; B81B 2203/033; B81B 2203/0361; B81B 2203/04; B81C 2201/013; B81C 2201/016; B81C 2201/0174

(57) ABSTRACT

A sealed cavity for a capacitive sensing device is presented herein. A micro-electro-mechanical system sensor comprises a capacitive sense element comprising a backplate and a diaphragm, in which the backplate comprises a first backplate portion and a second backplate portion, the diaphragm comprises a first diaphragm portion and a second diaphragm portion, the first backplate portion comprises an electrode of the capacitive sense element, and the capacitive sense element converts an external pressure that has been applied to the diaphragm into an electrical signal; and a sealed cavity that has been formed between the backplate and the diaphragm.

### CROSS-REFERENCE TO RELATED APPLICATION

This patent application claims priority to U.S. Provisional Patent Application No. 63/562,509, filed on Mar. 7, 2024, and entitled “VACUUM CAVITY FOR CAPACITIVE SENSING MICROPHONE,” the entirety of which is hereby incorporated by reference herein.

### TECHNICAL FIELD

This disclosure generally relates to embodiments for a sealed cavity for a capacitive sensing device.

### BACKGROUND

A conventional microphone utilizes a membrane and a backplate to sense sound. Changes in air pressure cause the membrane to move, which changes a capacitance of a sensing gap between the membrane and the backplate, and generates an electrical signal representing sound sensed by a microphone. An area between the membrane and a package of the microphone is a back chamber (or back volume), and a larger back volume enables the membrane to move more freely-correspondingly increasing a sensitivity of the microphone. Unfortunately, increasing a size of the back volume increases a package size of the microphone and consumes valuable semiconductor real estate.

Further, a membrane of a conventional microphone is susceptible to breaking and/or cracking in response to larger sound pressures being applied to the membrane. Moreover, gap(s) in a structure, e.g., a spring, corresponding to the membrane and/or gaps in a perforated backplate allow particles into the back volume that can increase noise and negatively affect a signal-to-noise ratio (SNR) of the microphone. Consequently, conventional microphone technologies have had some drawbacks, some of which may be noted with reference to the various embodiments described herein.

### BRIEF DESCRIPTION OF THE DRAWINGS

Non-limiting embodiments of the subject disclosure are described with reference to the following figures, wherein like reference numerals refer to like parts throughout the various views unless otherwise specified:

FIGS. 1-3 illustrate diagrams of a cross section of a micro-electro-mechanical system (MEMS) capacitive sensing device comprising a sealed cavity that has been formed between a backplate and a diaphragm of the MEMS capacitive sensing device, in accordance with various example embodiments;

FIG. 4 illustrates a diagram of a portion of a cross section of a MEM capacitive sensing device comprising capacitances corresponding to respective gaps that have been formed between respective portions of a backplate and a diaphragm of the MEMS capacitive sensing device, in accordance with various example embodiments;

FIG. 5 illustrates a diagram of a cross section of a MEMS capacitive sensing device comprising a sealed cavity that has been formed between a backplate and a diaphragm of the MEMS capacitive sensing device, in which the backplate and the diaphragm are attached to a substrate of the MEMS sensor at a periphery of the substrate, in accordance with various example embodiments;

FIG. 6 illustrates a cross section of another MEMS capacitive sensing device that comprises a sealed cavity that has been formed between a backplate and a diaphragm of the MEMS capacitive sensing device, in accordance with various example embodiments;

FIG. 7 illustrates a diagram of a top view of a donut-shaped diaphragm of a MEMS capacitive sensing device comprising a sealed cavity that has been formed between a backplate and the donut-shaped diaphragm, in accordance with various example embodiments;

FIG. 8 illustrates a diagram of portions of a donut-shaped diaphragm of a MEMS capacitive sensing device comprising a sealed cavity that has been formed between a backplate and the donut-shaped diaphragm, in which the portions of the donut-shaped diaphragm have been flexed-in response to an external pressure that has been applied to the donut-shaped diaphragm-more than remaining portions of the donut-shaped diaphragm, in accordance with various example embodiments;

FIG. 9 illustrates a diagram of a top view of a donut-shaped diaphragm of a MEMS capacitive sensing device comprising a sealed cavity that has been formed between a backplate and the donut-shaped diaphragm, in which the donut-shaped diaphragm comprises a donut-shaped electrode, in accordance with various example embodiments;

FIG. 10 illustrates a diagram of a top view of a square-shaped diaphragm of a MEMS capacitive sensing device comprising a sealed cavity that has been formed between a backplate and the square-shaped diaphragm, in accordance with various example embodiments;

FIG. 11 illustrates a diagram of a top view of a serpentine diaphragm of a MEMS capacitive sensing device comprising a sealed cavity that has been formed between a backplate and the serpentine diaphragm, in accordance with various example embodiments;

FIGS. 12-13 illustrate a method of manufacturing a MEMS capacitive sensing device comprising a sealed cavity that has been formed between a backplate and a diaphragm of the MEMS capacitive sensing device, in accordance with various example embodiments; and

FIGS. 14-31 illustrate diagrams of respective cross-sections of a MEMS capacitive sensing device during respective steps of manufacture of the MEMS capacitive sensing device, in which the MEMS capacitive sensing device comprises a sealed cavity that has been formed between a backplate and a diaphragm of the MEMS capacitive sensing device, in accordance with various example embodiment(s).

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

As described above, increasing a size of a back volume of a microphone increases a package size of the microphone and consumes valuable semiconductor real estate. Further, a membrane of a conventional microphone is susceptible to breaking and/or cracking in response to larger sound pressures being applied to the membrane. Furthermore, gap(s) in a structure, e.g., a spring, corresponding to the membrane and/or gaps in a perforated backplate allow particles into the back volume that can increase noise and negatively affect an SNR of the microphone. Various embodiments disclosed herein can facilitate a reduction of a package size of a capacitive sensing device, improve a noise performance of the capacitive sensing device, and prevent damage to a diaphragm of the capacitive sensing device by forming a sealed cavity between a backplate of the capacitive sensing device and the diaphragm, and constraining a movement of the diaphragm within the sealed cavity.

For example, in embodiment(s), a MEMS sensor, e.g., a MEMS microphone, a MEMS pressure sensor, or a MEMS capacitive micromachined ultrasonic transducer, comprises: a capacitive sense element comprising a backplate and a diaphragm, in which the backplate comprises a first backplate portion and a second backplate portion, in which the diaphragm comprises a first diaphragm portion and a second diaphragm portion, in which the first backplate portion comprises an electrode of the capacitive sense element, and in which the capacitive sense element converts an external pressure that has been applied to the diaphragm into an electrical signal; and a sealed cavity, e.g., comprising a pressure less than 100 pascals, which has been formed between the backplate and the diaphragm, in which a first gap has been formed between the first backplate portion and the first diaphragm portion, and in which a second gap, e.g., at least one order of magnitude greater than the first gap, has been formed between the second backplate portion and the second diaphragm portion.

In other embodiment(s), MEMS microphone comprises: a silicon-based substrate comprising an opening that comprises a sound port of the MEMS microphone; a capacitive sense element comprising a diaphragm and a backplate, in which the capacitive sense element converts an acoustic pressure into an electrical signal, in which the diaphragm is anchored along an outer periphery of the silicon-based substrate, and in which the backplate comprises a pillar-type electrode of the capacitive sense element; and a sealed cavity that has been created between the diaphragm and the backplate comprising the pillar-type electrode.

In yet other embodiment(s), a method of manufacturing a MEMS sensor comprises: depositing a first oxide layer over a substrate and forming a first polysilicon layer on the substrate to form a diaphragm; depositing a second oxide layer on the first polysilicon layer to form a first gap corresponding to an electrode of a capacitive sense element; depositing and patterning a second polysilicon layer on the second oxide layer to form a base of the electrode of the capacitive sense element, in which the electrode comprises an array of pillars of polysilicon; depositing a third oxide layer on the second polysilicon layer to facilitate defining a height of the array of pillars of polysilicon of the electrode; depositing a third polysilicon layer on the second polysilicon layer and the third oxide layer to form a backplate of the capacitive sense element comprising the array of pillars of polysilicon of the electrode; providing etch holes in the third polysilicon layer to facilitate generation of a low pressure sealed cavity between the diaphragm and the backplate, in which the low pressure sealed cavity comprises a first pressure that is lower than a second pressure of an area outside of the low pressure sealed cavity; performing an oxide release to facilitate generation of the low pressure sealed cavity; and depositing a silicon-based layer on the third polysilicon layer to seal the low pressure sealed cavity at the first pressure.

Reference throughout this specification to “one embodiment,” or “an embodiment,” means that a particular feature, structure, or characteristic described in connection with the embodiment is included in at least one embodiment. Thus, the appearances of the phrase “in one embodiment,” or “in an embodiment,” in various places throughout this specification are not necessarily all referring to the same embodiment. Furthermore, the particular features, structures, or characteristics may be combined in any suitable manner in one or more embodiments.

Furthermore, to the extent that the terms “includes,” “has,” “contains,” and other similar words are used in either the detailed description or the appended claims, such terms are intended to be inclusive-in a manner similar to the term “comprising” as an open transition word-without precluding any additional or other elements. Moreover, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Furthermore, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art.

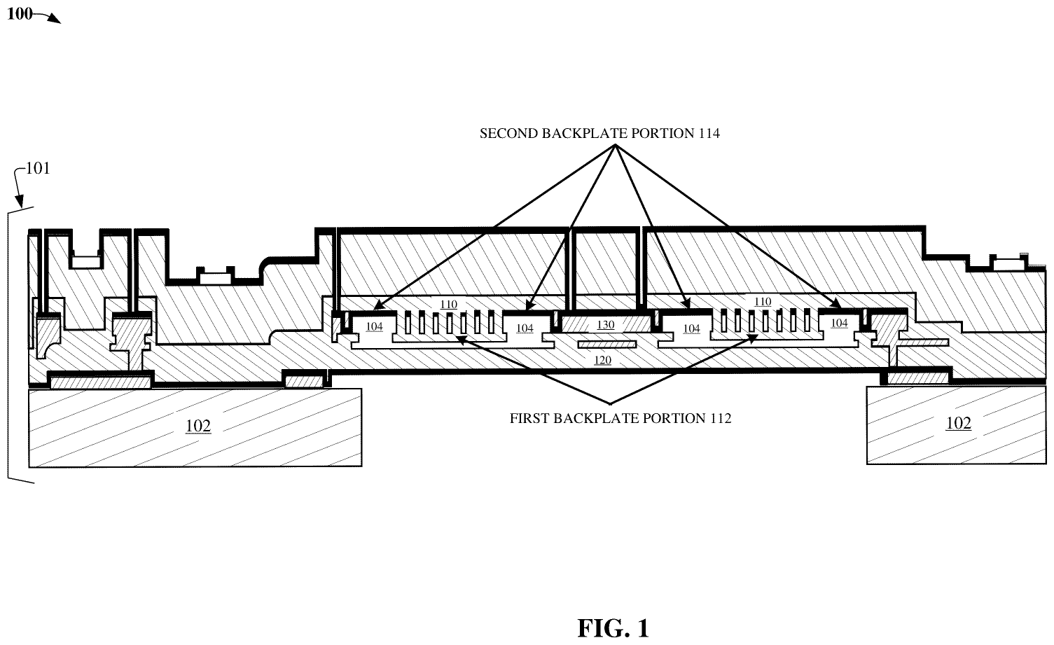

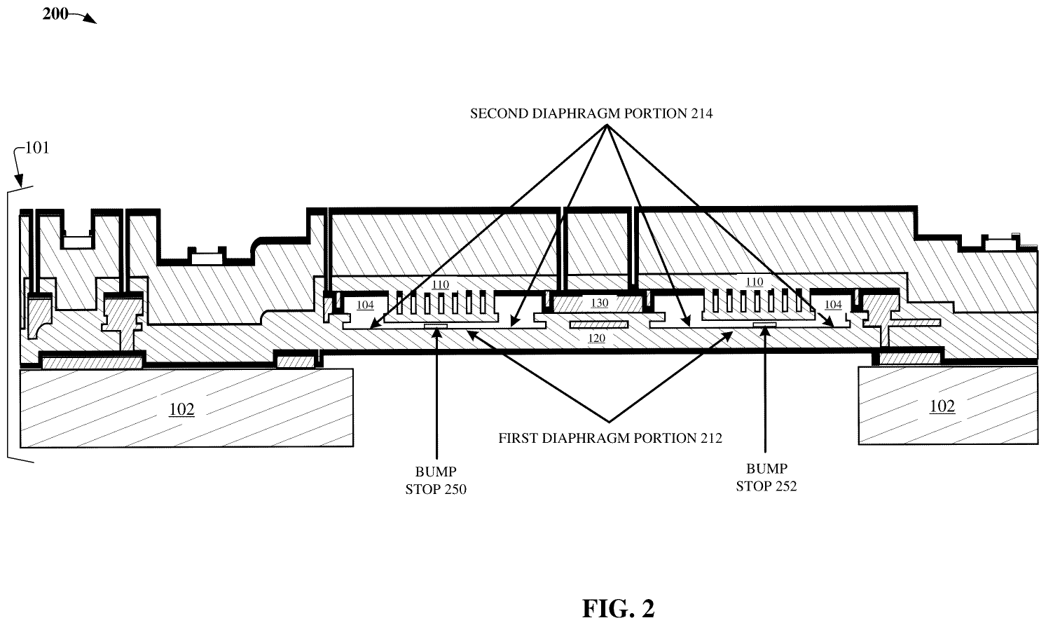

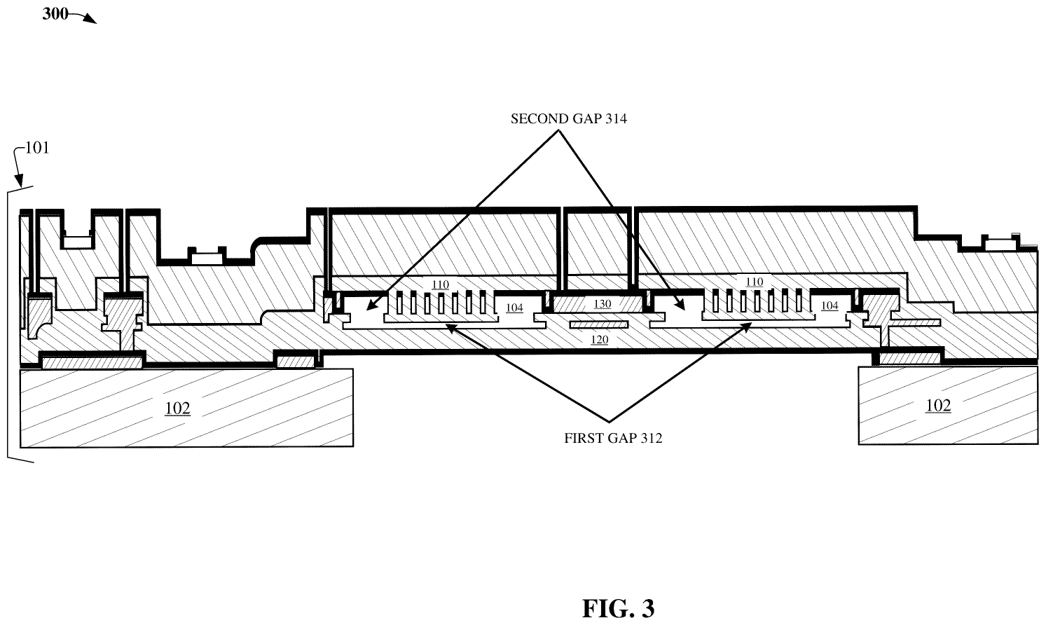

Referring now to FIGS. 1-3, diagrams (100, 200, 300) of a cross section of a MEMS capacitive sensing device (101), e.g., a MEMS microphone, a MEMS pressure sensor, or a MEMS capacitive micromachined ultrasonic transducer, which comprises a sealed cavity (104) that has been formed between a backplate (110) and a diaphragm (120) of the MEMS capacitive sensing device are illustrated, in accordance with various example embodiments. The backplate comprises a first backplate portion (112) and a second backplate portion (114). In embodiment(s), the first backplate portion comprises an electrode of a capacitive sense element that converts an external pressure that has been applied to the diaphragm into an electrical signal.

The diaphragm comprises a first diaphragm portion (212) and a second diaphragm portion (214). In other embodiment(s), the electrode, e.g., a pillar-type electrode, comprises pillars extending into a sealed cavity (104) that has been formed between the backplate and the diaphragm. In embodiment(s), the sealed cavity comprises a pressure that is less than 100 pascals.

In other embodiment(s), the first diaphragm portion comprises one or more bump stops (e.g., 250, 252) that restrict a movement of the first diaphragm portion. In yet other embodiment(s), the bump stop(s) can be formed along a shape of the diaphragm and/or in the shape of the diaphragm, so as to restrict the movement of the first diaphragm.

A first gap (312) has been formed between the first backplate portion and the first diaphragm portion, and a second gap (314) has been formed between the second backplate portion and the second diaphragm portion.

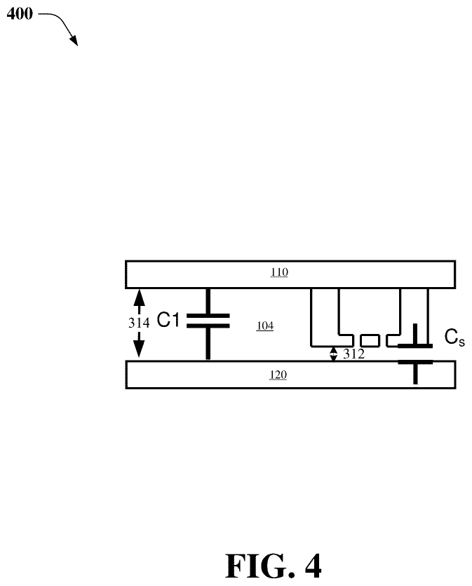

In embodiment(s) illustrated by FIG. 4, the first gap corresponds to the capacitive sense element and forms a sensing capacitance (“Cs”) (e.g., which is less than 500 nm), and the second gap is, e.g., 1-10 microns, which is an order of magnitude greater than the first gap, e.g., a second gap capacitance (“C1”) corresponding to the second gap is much less than Cs and does not influence the overall performance of the MEMS capacitive sensing device.

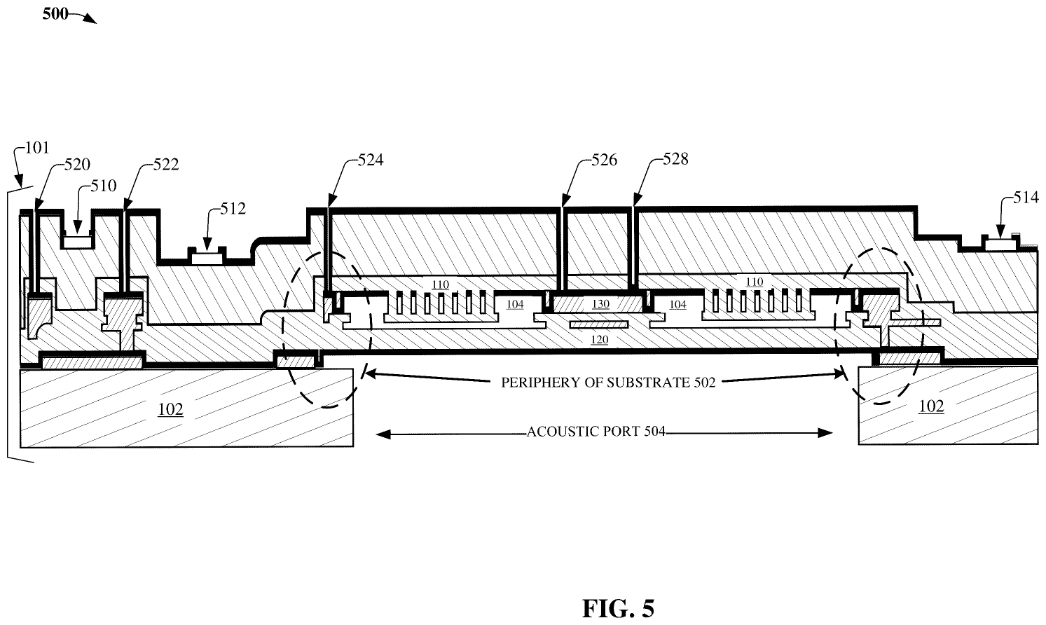

Referring now to embodiment(s) illustrated by FIG. 5, the backplate and the diaphragm are attached to a substrate (102) of the MEMS sensor at a periphery (502) of the substrate. Further, the MEMS sensor comprises an acoustic port (504) that has been formed by an opening in the substrate. Furthermore, the backplate and the diaphragm are attached to a post (130), e.g., which is located substantially at a center of the diaphragm. In this regard, the post electrically isolates the diaphragm from the backplate.

In other embodiment(s), respective electrical contacts of the backplate and the diaphragm comprise respective contact pads (e.g., 510, 512, 514); and the backplate comprises a plurality of trenches (e.g., 520, 522, 524, 526, 528) that electrically isolate the respective contact pads.

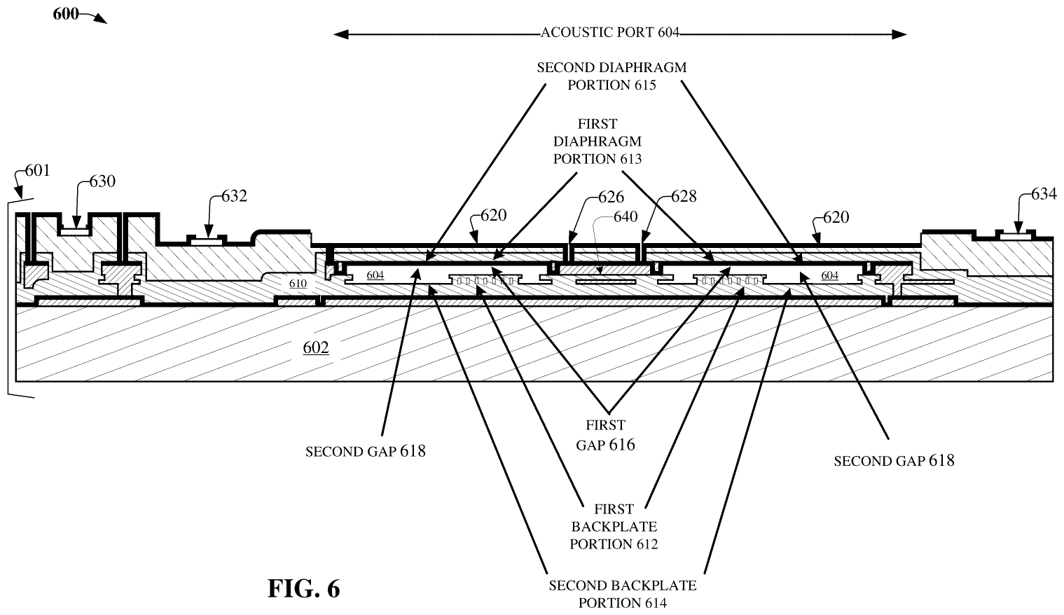

FIG. 6 illustrates a cross section of a MEMS capacitive sensing device (601), e.g., a MEMS microphone, a MEMS pressure sensor, or a MEMS capacitive micromachined ultrasonic transducer, which comprises a sealed cavity (604) that has been formed between a backplate (610) and a diaphragm (620) of the MEMS capacitive sensing device, in accordance with various example embodiments.

The backplate comprises a first backplate portion (612) and a second backplate portion (614). In embodiment(s), the first backplate portion comprises an electrode of a capacitive sense element that converts an external pressure that has been applied to the diaphragm into an electrical signal.

The diaphragm comprises a first diaphragm portion (613) and a second diaphragm portion (615). In other embodiment(s), the electrode, e.g., a pillar-type electrode, comprises pillars extending into the sealed cavity that has been formed between the backplate and the diaphragm. In embodiment(s), the sealed cavity comprises a pressure that is less than 100 pascals.

In other embodiment(s), the first diaphragm portion comprises one or more bump stops (not shown) that restrict a movement of the first diaphragm portion. In yet other embodiment(s), the bump stop(s) can be formed along a shape of the diaphragm and/or in the shape of the diaphragm, so as to restrict the movement of the first diaphragm.

A first gap (616) has been formed between the first backplate portion and the first diaphragm portion, and a second gap (618) has been formed between the second backplate portion and the second diaphragm portion.

In embodiment(s), the first gap corresponds to the capacitive sense element and forms a sensing capacitance (“Cs”), e.g., which is less than 500 nm, and the second gap is, e.g., 1-10 microns, which is an order of magnitude greater than the first gap.

Further, the MEMS capacitive sensing device comprises an acoustic port (604) that has been formed adjacent to the diaphragm. Furthermore, the backplate and the diaphragm are attached to a post (640), e.g., which is located substantially at a center of the diaphragm. In this regard, the post electrically isolates the diaphragm from the backplate.

In other embodiment(s), respective electrical contacts of the backplate and the diaphragm comprise respective contact pads (e.g., 630, 632, 634); and the membrane comprises a plurality of trenches (e.g., 626, 628) that electrically isolate the respective contact pads.

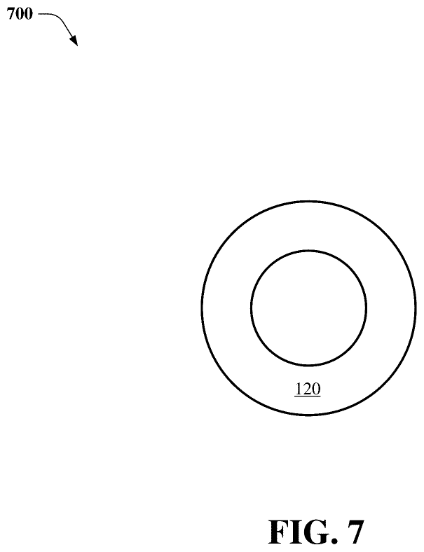

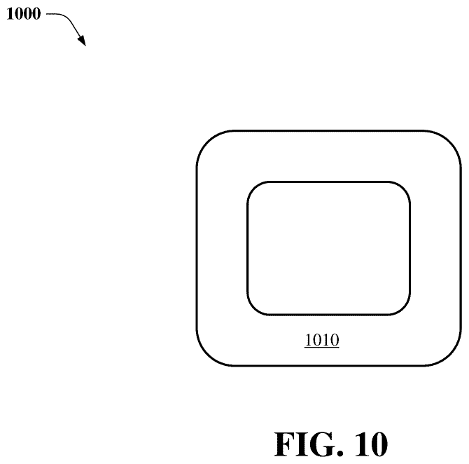

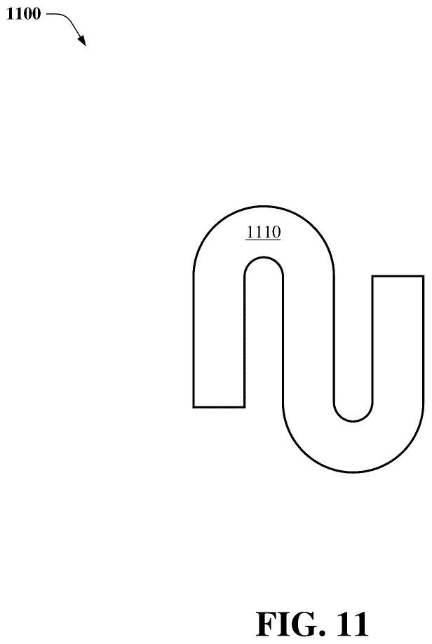

In various embodiment(s) illustrated by FIGS. 7-11, a shape of the diaphragm, e.g., as viewed from a top of the diaphragm, is circular, donut-shaped (e.g., 120), rectangular (e.g., 100), or serpentine (e.g., 1110). In this regard, the first backplate portion comprising the electrode comprises an array of pillars formed along the shape of the diaphragm, e.g., the pillar-type electrode comprising a circular array of pillars, a donut-shaped shaped array of pillars, a rectangular array of pillars, or a serpentine array of pillars.

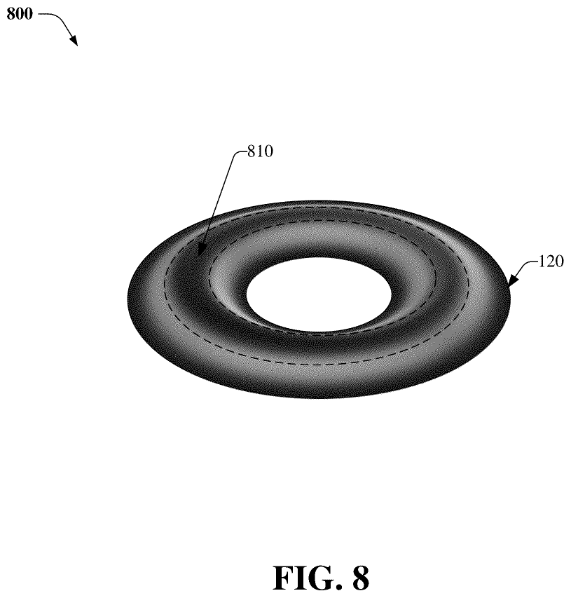

In embodiment(s) illustrated by FIG. 8, portions (810) of the donut-shaped diaphragm (120) of the MEMS capacitive sensing device have been flexed-in response to an external pressure that has been applied to the donut-shaped diaphragm-more than remaining portions of the donut-shaped diaphragm, in accordance with various example embodiments.

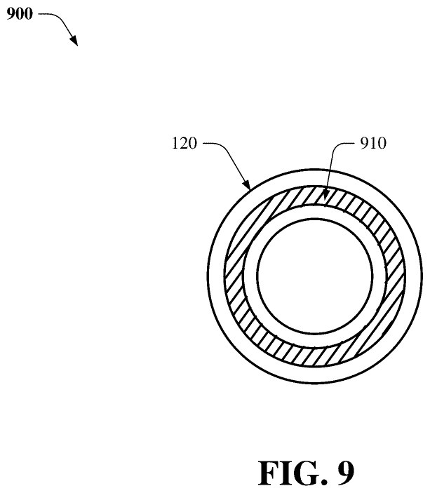

In other embodiment(s) illustrated by FIG. 9, the donut-shaped diaphragm comprises a donut-shaped electrode (910) that is embedded within the donut-shaped diaphragm to facilitate an increase in sensing, via the capacitive sense element, of the electrical signal representing the external pressure that has been applied to the diaphragm.

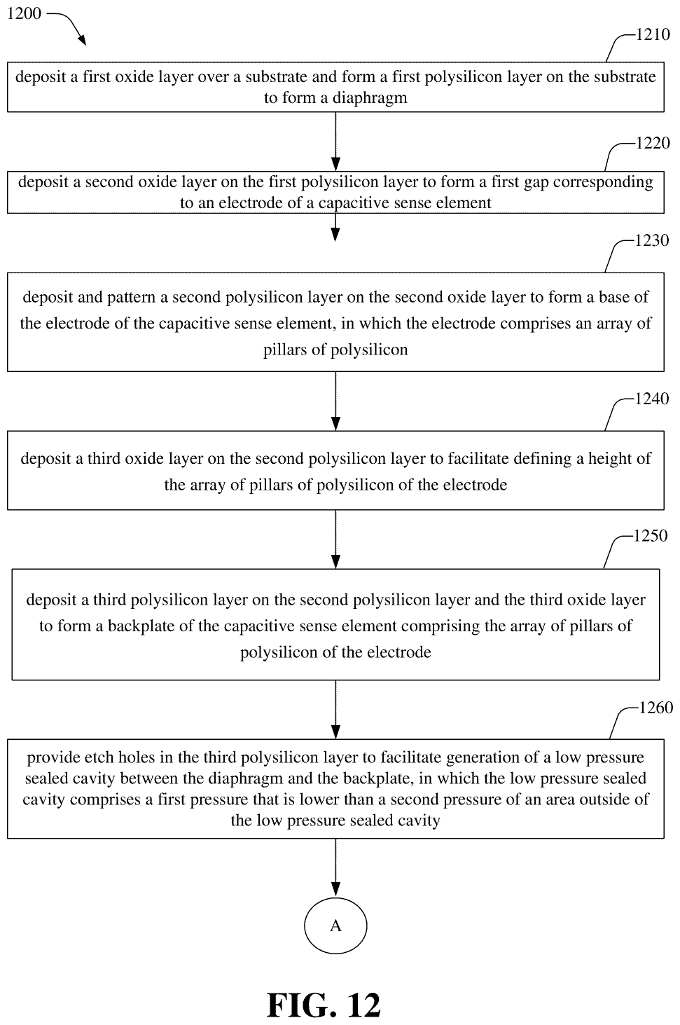

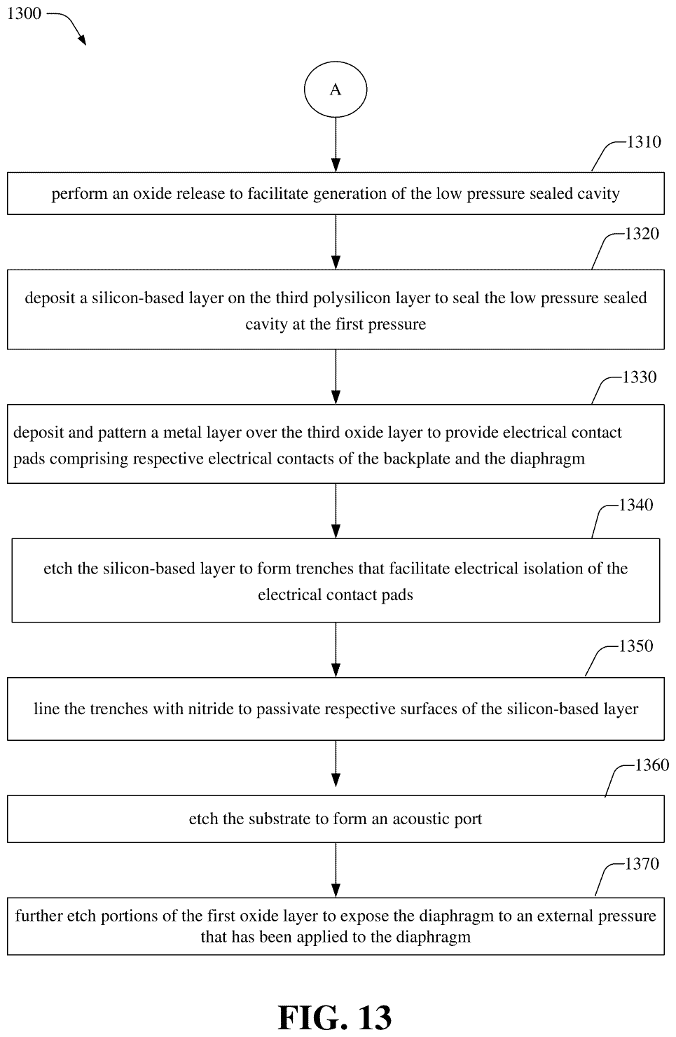

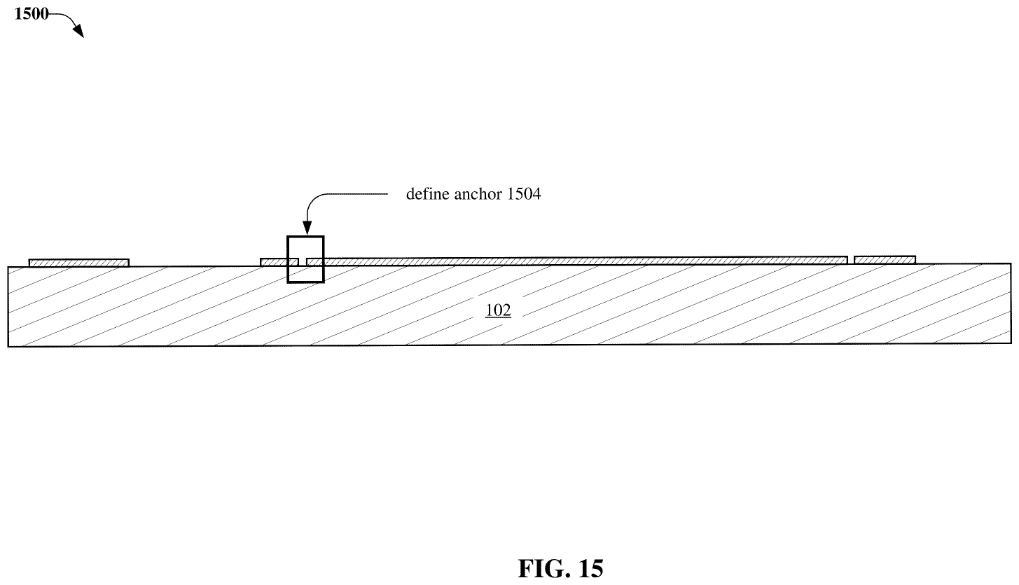

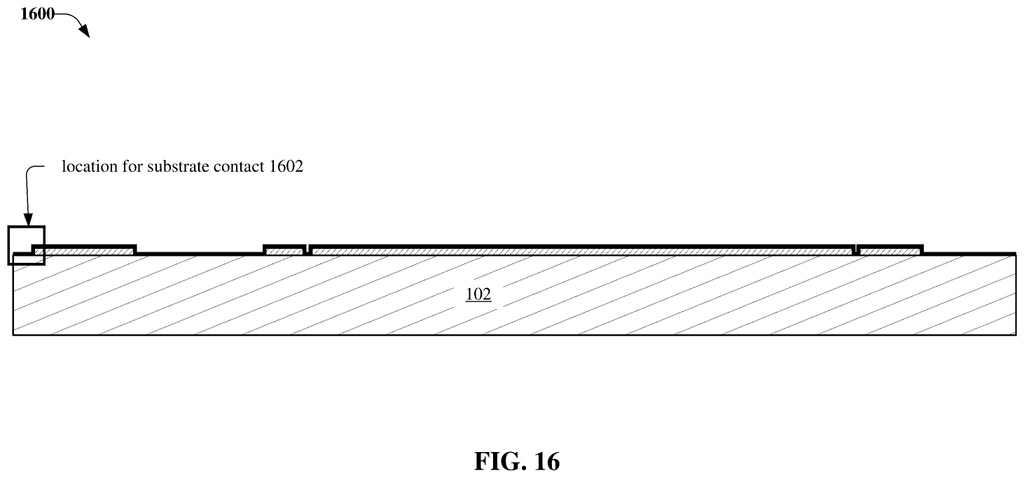

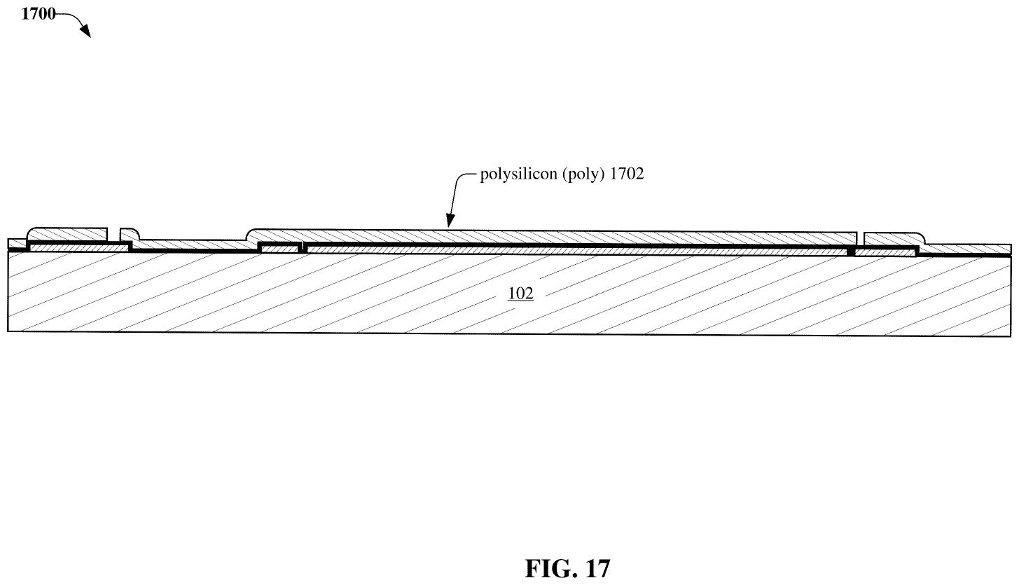

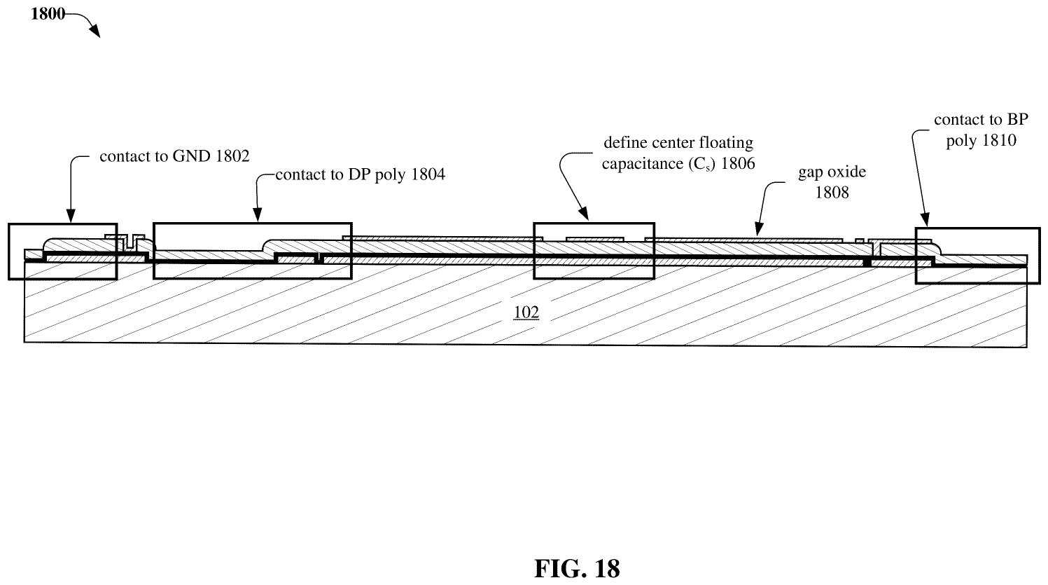

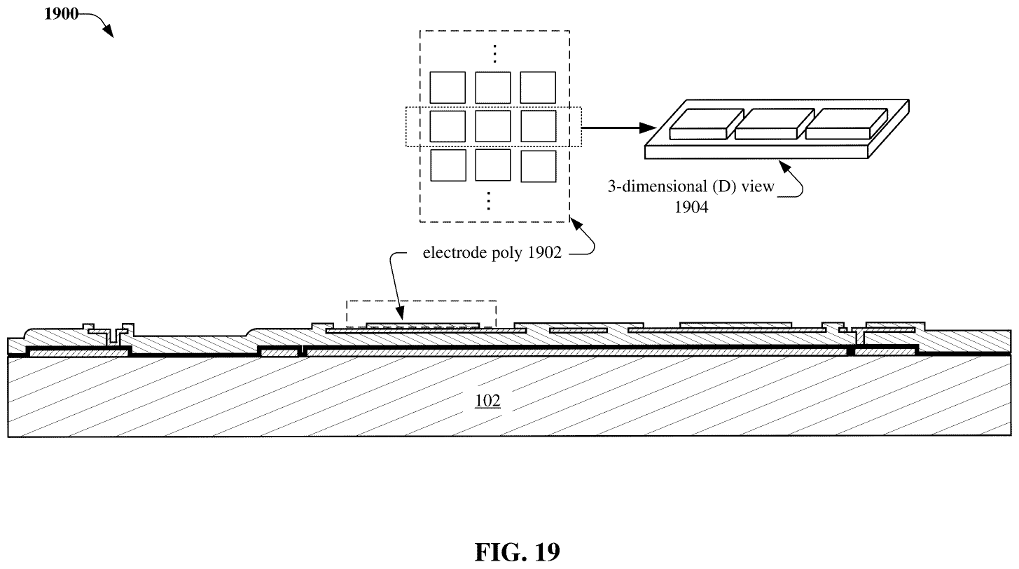

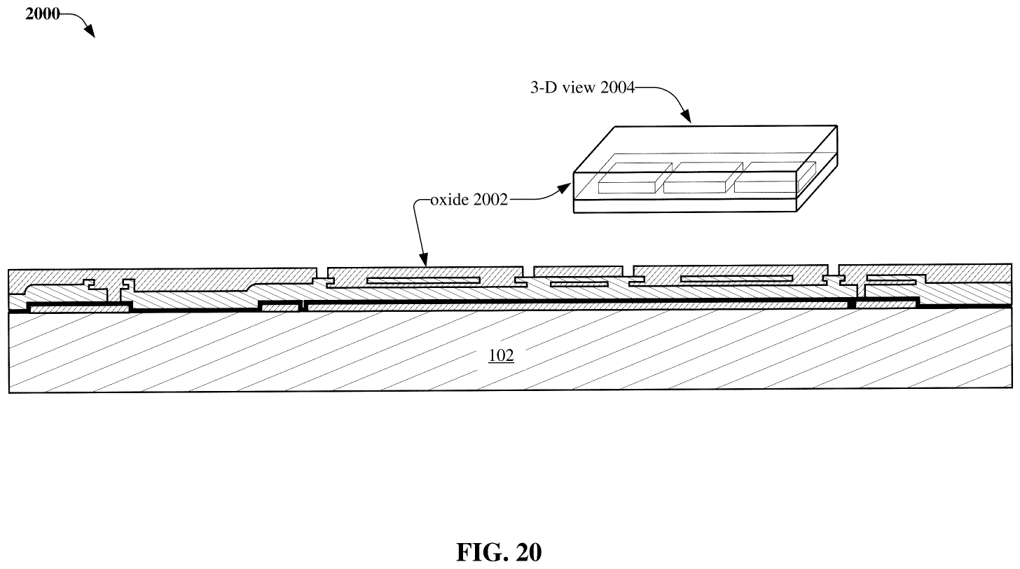

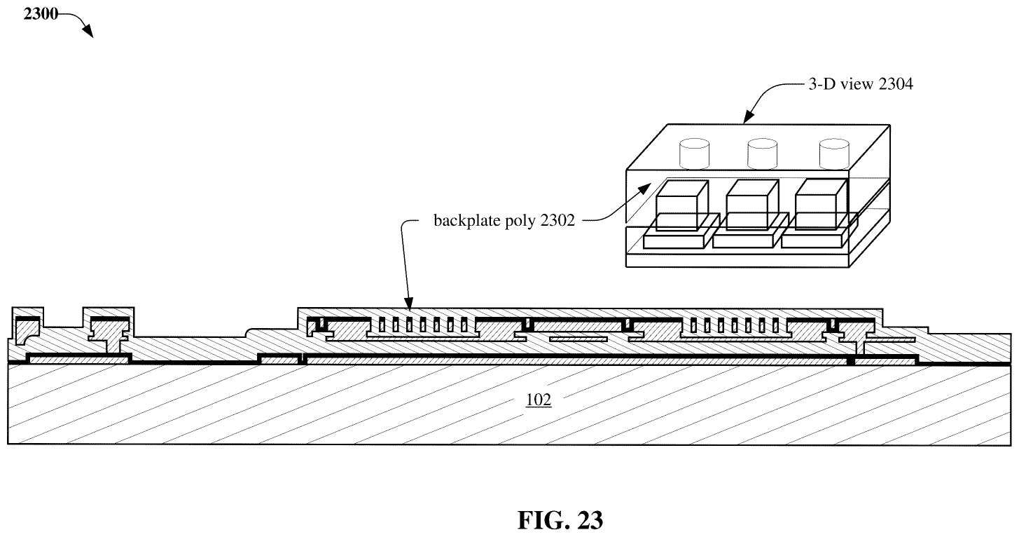

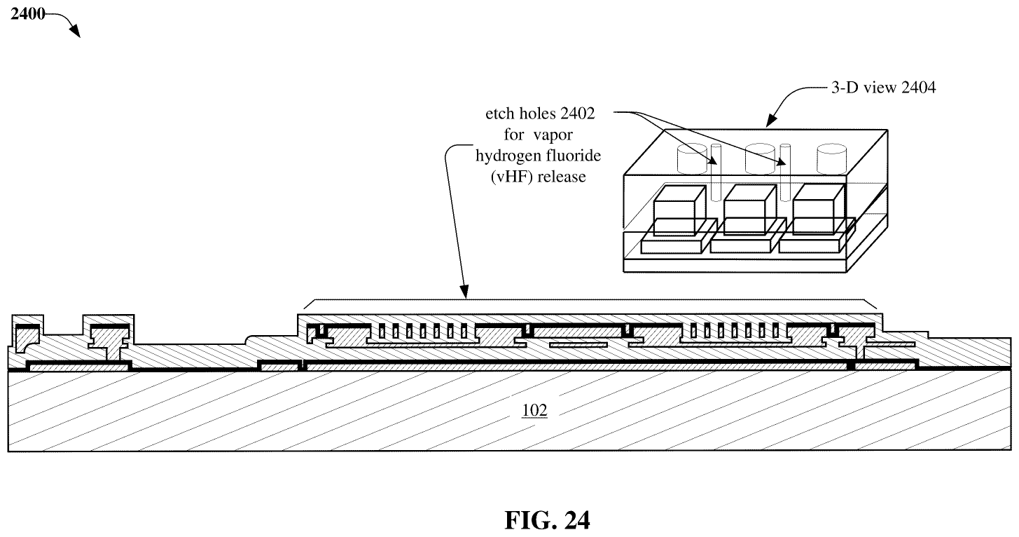

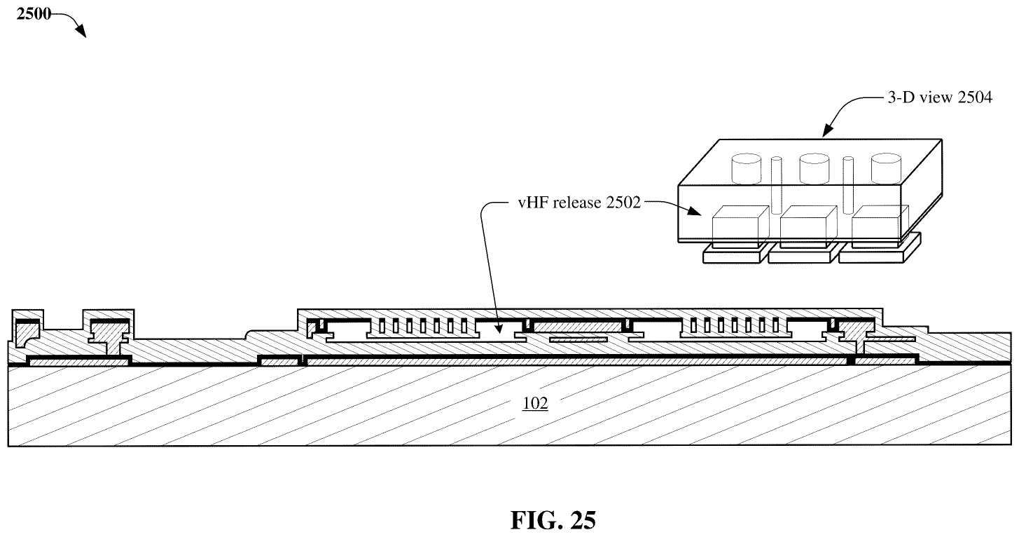

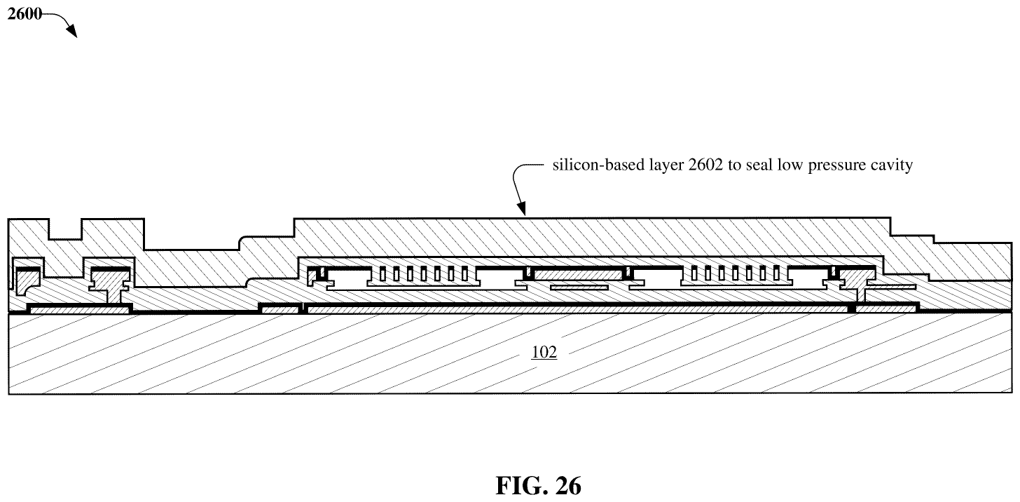

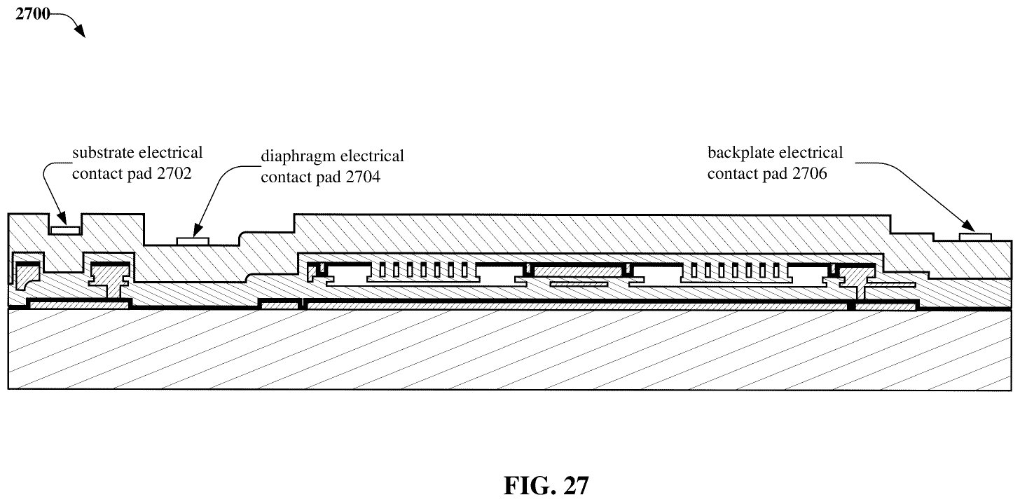

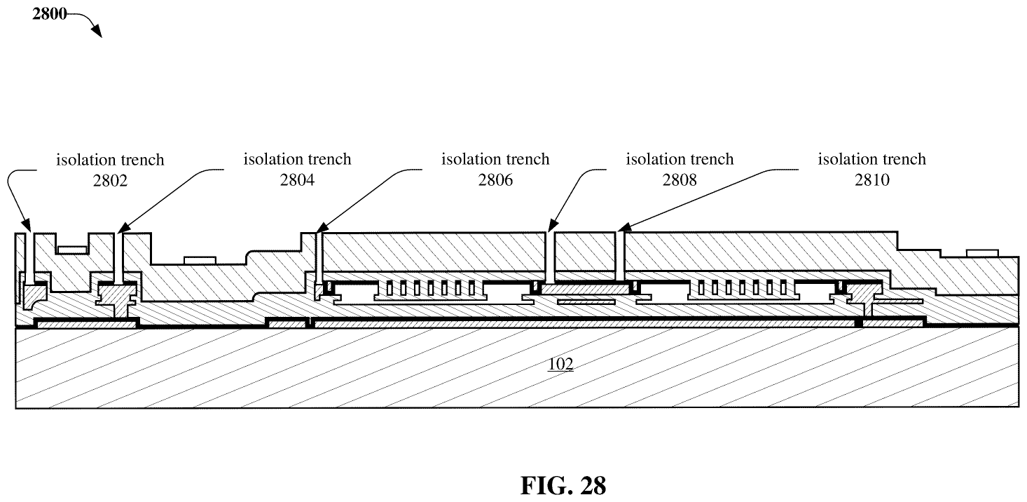

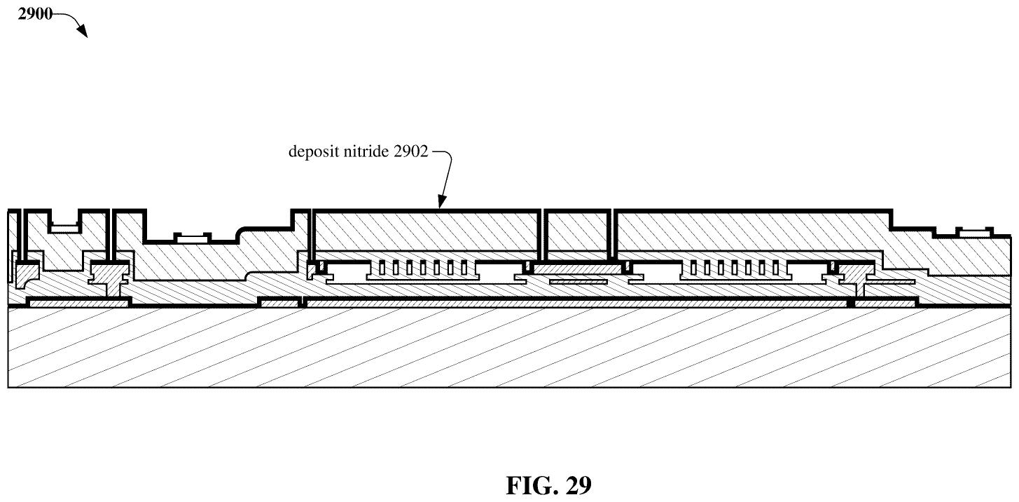

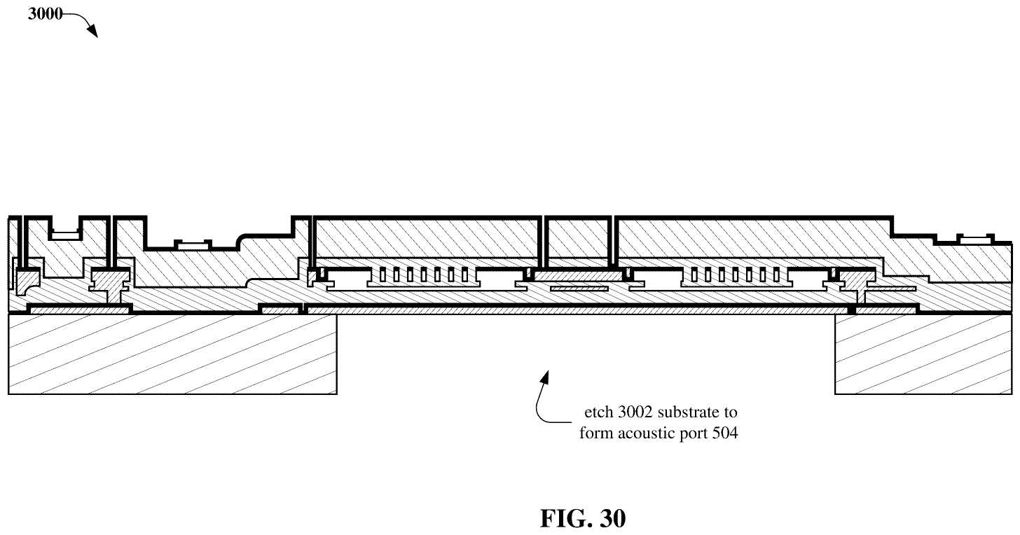

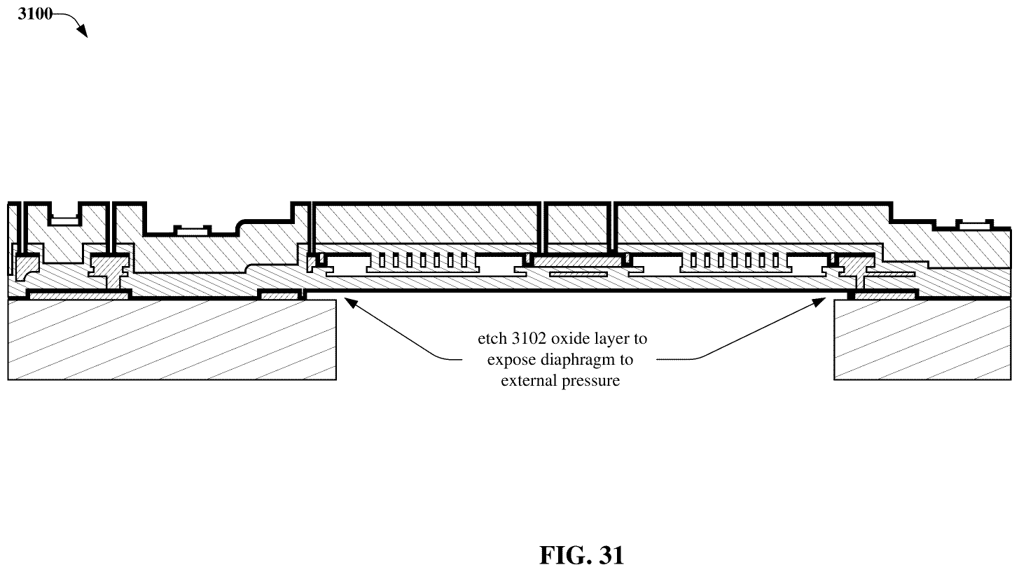

Now referring to FIGS. 12-31, diagrams of a method of manufacturing a MEMS capacitive sensing device (101) comprising a sealed cavity that has been formed between a backplate and a diaphragm of the MEMS capacitive sensing device, and respective cross-sections of the MEMS capacitive sensing device during respective steps of the manufacturing of the MEMS capacitive sensing device are illustrated, respectively, in accordance with various example embodiments.

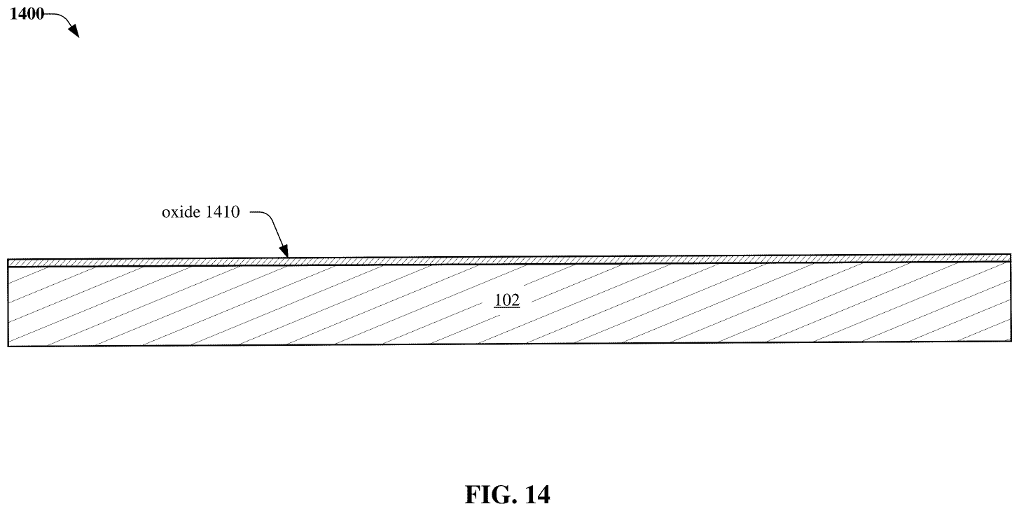

As illustrated by FIGS. 14-16, an oxide 1410, or a first oxide layer, e.g., an inter-layer dielectric (ILD), is formed and/or deposited on a substrate (102); a mask is applied to the oxide to define an anchor 1504 (e.g., mechanical anchor) to the substrate; and another mask is applied, utilizing a layer of low-stress silicon nitride (LSN), to at least define a location for a contact to be formed on the substrate.

In turn, and referring now to FIGS. 12-13 and 17-31, at 1210, a first oxide layer is deposited over the substrate and then a first polysilicon (poly) 1702 layer is formed and/or deposited on the substrate, e.g., on the layer of LSN, to form a diaphragm. At 1220, second oxide layer, e.g., gap oxide 1808, is formed and/or deposited on the first poly layer to form a first gap corresponding to an electrode of a capacitive sense element, e.g., corresponding to center floating capacitance (“Cₛ”) 1806; to form contact to GND 1802 (e.g., substrate contact 1602); to form contact to DP poly 1804; and to form contact to BP poly 1810.

At 1230, a second poly layer, e.g., comprising electrode poly 1902, is formed and/or deposited (e.g., via a mask pattern) on the second oxide layer to form a base of the electrode of the capacitive sense element, in which the base of the electrode comprises an array base of an array of pillars of poly, e.g., formed along a shape (e.g., circular, donut-shaped, rectangular) of the diaphragm. In an embodiment, a portion of the array base of pillars comprises a row of three pillars. In another embodiment, each pillar of the array base of pillars is approximately, e.g., within 1% of, 5 micrometers in length and 5 micrometers in width (see, e.g., 3-dimensional (D) view 1904), and the array base of pillars comprises rows comprising the row that have been formed along the shape of diaphragm.

At 1240, a third oxide layer, e.g., oxide 2002 (e.g., an ILD), is formed and/or deposited (e.g., via a mask pattern) on the second poly layer to facilitate defining a height of the array of pillars of poly of the electrode of the capacitive sense element. (See, e.g., 3-D view 2004).

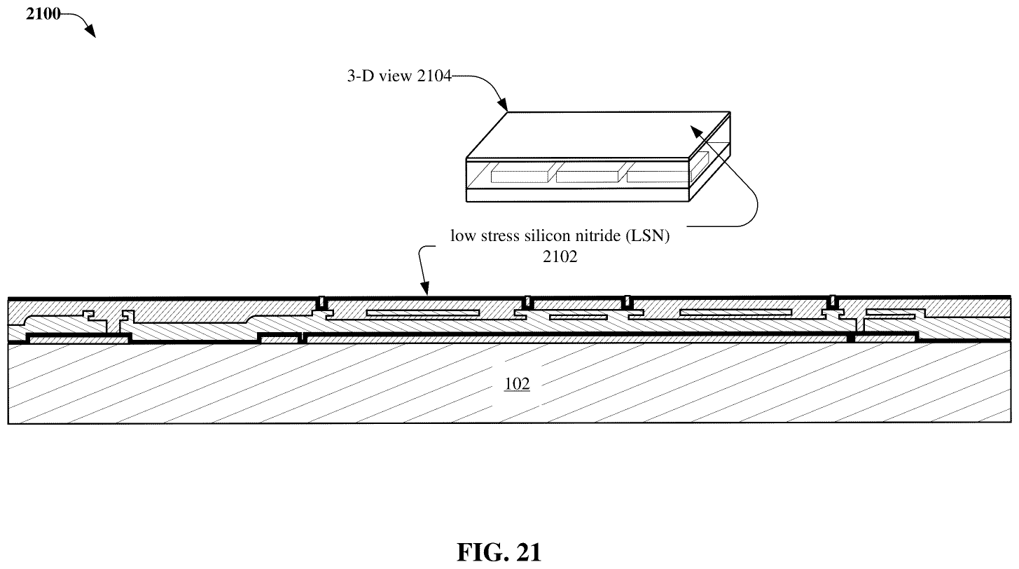

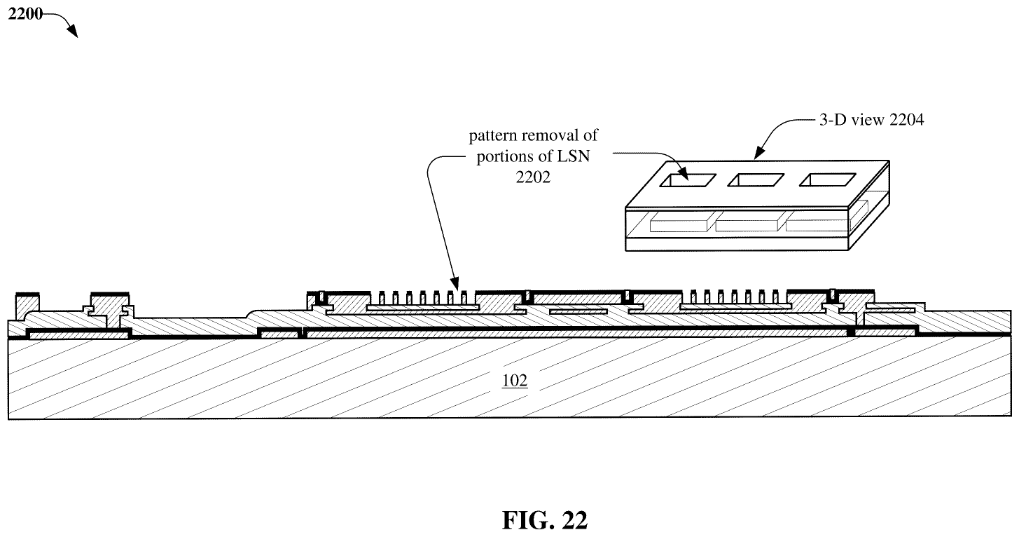

In turn, as illustrated by FIGS. 21 and 22, a layer of LSN, e.g., LSN 2102, is formed and/or deposited on the third oxide layer (see, e.g., 3-D view 2104); and portions (2202) of the layer of LSN are removed, e.g., via a mask pattern, to expose respective portions of the second poly layer to facilitate expansion (e.g., see 3-D view 2304) of the array of pillars of poly from the array base of pillars. (See, e.g., 3-D view 2204).

In this regard, at 1250, a third poly layer, e.g., backplate poly 2302, is formed and/or deposited on the second poly layer and the third oxide layer to form a backplate of the capacitive sense element comprising the array of pillars of poly of the electrode of the capacitive sense element.

At 1260, etch holes (2402) are provided, created, and/or formed (see, e.g., 3-D view 2404) in the third poly layer to facilitate, e.g., via a vapor hydrogen fluoride (vHF) release, generation of a low pressure sealed cavity between the diaphragm and the backplate, in which the low pressure sealed cavity comprises a first pressure that is lower than a second pressure of an area outside of the low pressure sealed cavity.

At 1310, an oxide release (e.g., vHF release 2502) is performed to facilitate generation of the low pressure sealed cavity (see, e.g., 3-D view 2504); and at 1320, a silicon-based layer (2602) is formed and/or deposited on the third poly layer to seal the low pressure sealed cavity at the first pressure.

At 1330, a metal layer is formed and/or deposited, e.g., via a mask pattern, over and/or on the third oxide layer to provide electrical contact pads (e.g., substrate electrical contact pad 2702, diaphragm electrical contact pad 2704, and backplate electrical contact pad 2706) comprising respective electrical contacts of the backplate and the diaphragm.

At 1340, the silicon-based layer is etched to form trenches, or isolation trenches (e.g., 2802, 2804, 2806, 2808, 2810), which facilitate electrical isolation of the electrical contact pads.

At 1350, the trenches are lined and/or deposited with nitride (2902) to passivate respective surfaces of the silicon-based layer.

At 1360, the substrate is etched (3002) to form an acoustic port (504).

At 1370, portions of the first oxide layer are etched (3102) to expose the diaphragm to an external pressure that has been applied to the diaphragm.

The above description of illustrated embodiments of the subject disclosure, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. A micro-electro-mechanical system (MEMS) sensor, comprising:
a capacitive sense element comprising a backplate and a diaphragm, wherein the backplate comprises a first backplate portion and a second backplate portion, wherein the diaphragm comprises a first diaphragm portion and a second diaphragm portion, wherein the first backplate portion comprises an electrode of the capacitive sense element, and wherein the capacitive sense element converts an external pressure that has been applied to the diaphragm into an electrical signal; and
a sealed cavity that has been formed between the backplate and the diaphragm.

2. The MEMS sensor of claim 1, wherein a first gap has been formed between the first backplate portion and the first diaphragm portion, and wherein a second gap has been formed between the second backplate portion and the second diaphragm portion.

3. The MEMS sensor of claim 1, wherein the backplate is attached to a substrate of the MEMS sensor, wherein the diaphragm is attached to the backplate, and wherein the backplate is positioned between the substrate and the diaphragm.

4. The MEMS sensor of claim 1, wherein the diaphragm is attached to a substrate of the MEMS sensor, wherein the backplate is attached to the diaphragm, and wherein the diaphragm is positioned between the substrate and the backplate.

5. The MEMS sensor of claim 4, further comprising an acoustic port that has been formed by an opening in the substrate.

6. The MEMS sensor of claim 1, wherein the backplate and the diaphragm are attached to a post.

7. The MEMS sensor of claim 6, wherein the post is located substantially at a center of the diaphragm.

8. The MEMS sensor of claim 6, wherein the post electrically isolates the diaphragm from the backplate.

9. The MEMS sensor of claim 1, wherein respective electrical contacts of the backplate and the diaphragm comprise respective contact pads, and wherein the backplate comprises a plurality of trenches that electrically isolate the respective contact pads.

10. The MEMS sensor of claim 1, wherein the first diaphragm portion comprises a bump stop that restricts a movement of the first diaphragm portion.

11. The MEMS sensor of claim 1, wherein the first backplate portion comprising the electrode comprises pillars extending into the sealed cavity.

12. The MEMS sensor of claim 1, wherein a shape of the diaphragm is circular, donut-shaped, or rectangular, and wherein the first backplate portion comprising the electrode comprises an array of pillars formed along the shape of the diaphragm.

13. The MEMS sensor of claim 1, wherein the sealed cavity comprises a pressure that is less than 100 pascals.

14. The MEMS sensor of claim 1, wherein the external pressure comprises a sound pressure, an atmospheric pressure, or an ultrasonic pressure.

15. The MEMS sensor of claim 2, wherein the second gap is at least one order of magnitude greater than the first gap.

16. A micro-electro-mechanical system (MEMS) microphone, comprising:
a silicon-based substrate comprising an opening that comprises a sound port of the MEMS microphone;
a capacitive sense element comprising a diaphragm and a backplate, wherein the capacitive sense element converts an acoustic pressure into an electrical signal, wherein the diaphragm is anchored to the silicon-based substrate, and wherein the backplate comprises a pillar-type electrode of the capacitive sense element; and
a sealed cavity that has been created between the diaphragm and the backplate comprising the pillar-type electrode.

17. The MEMS microphone of claim 16, wherein the diaphragm comprises a bump stop that restricts a movement of the diaphragm.

18. The MEMS microphone of claim 16, wherein the pillar-type electrode comprises a circular, rectangular, or serpentine array of pillars.

19. The MEMS microphone of claim 16, wherein the diaphragm and the backplate are attached to a post that is located substantially at a center of the backplate.

20. A method of manufacturing a micro-electro-mechanical system (MEMS) sensor, comprising:
depositing a first oxide layer over a substrate and forming a first polysilicon layer on the substrate to form a diaphragm;
depositing a second oxide layer on the first polysilicon layer to form a first gap corresponding to an electrode of a capacitive sense element;
depositing and patterning a second polysilicon layer on the second oxide layer to form a base of the electrode of the capacitive sense element, wherein the electrode comprises an array of pillars of polysilicon;
depositing a third oxide layer on the second polysilicon layer to facilitate defining a height of the array of pillars of polysilicon of the electrode;
depositing a third polysilicon layer on the second polysilicon layer and the third oxide layer to form a backplate of the capacitive sense element comprising the array of pillars of polysilicon of the electrode;
providing etch holes in the third polysilicon layer to facilitate generation of a low pressure sealed cavity between the diaphragm and the backplate, wherein the low pressure sealed cavity comprises a first pressure that is lower than a second pressure of an area outside of the low pressure sealed cavity;
performing an oxide release to facilitate generation of the low pressure sealed cavity; and
depositing a silicon-based layer on the third polysilicon layer to seal the low pressure sealed cavity at the first pressure.

21. The method of manufacturing the MEMS sensor of claim 20, further comprising:
depositing and patterning a metal layer over the third oxide layer to provide electrical contact pads comprising respective electrical contacts of the backplate and the diaphragm.

22. The method of manufacturing the MEMS sensor of claim 20, further comprising:
etching the silicon-based layer to form trenches that facilitate electrical isolation of the electrical contact pads.

23. The method of manufacturing the MEMS sensor of claim 20, further comprising:
lining the trenches with nitride to passivate respective surfaces of the silicon-based layer.

24. The method of manufacturing the MEMS sensor of claim 20, further comprising:
etching the substrate to form an acoustic port.

25. The method of manufacturing the MEMS sensor of claim 24, further comprising:
further etching portions of the first oxide layer to expose the diaphragm to an external pressure to be applied to the diaphragm.
